(19) United States
(12) Patent Application Publication
(10) Pub. No.: US 2024/0387456 A1
(43) Pub. Date: Nov. 21, 2024

(54) Package with Organic Integrated Circuit Substrate Embedded in Inorganic Carrier Body and Redistribution Structure Extending Along Both

(71) Applicant: AT&S Austria Technologie & Systemtechnik AG, Leoben (AT)

(72) Inventor: Minwoo LEE, Chongqing (CN)

(21) Appl. No.: 18/693,683

(22) PCT Filed: Jan. 26, 2023
(86) PCT No.: PCT/EP2023/051887

§ 371 Date: Mar. 20, 2024

(30) Foreign Application Priority Data
Jan. 28, 2022 (CN) 202210107360.6

(51) Int. Cl. H01L 25/065; H01L 21/48; H01L 23/00; H01L 23/498; H01L 23/538; H01L 23/544; H01L 25/16; H10B 80/00

(52) U.S. Cl. CPC H01L 25/0655; H01L 21/4853; H01L 21/4857; H01L 21/486; H01L 23/49822; H01L 23/49838; H01L 23/5381; H01L 23/5385; H01L 23/5386; H01L 23/544; H01L 24/06; H01L 24/16; H01L 25/16; H10B 80/00; H01L 2223/54426; H01L 2224/0231; H01L 2224/02331; H01L 2224/02379; H01L 2224/02381; H01L 2224/06182; H01L 2224/16227; H01L 2924/15311; H01L 2924/19041; H01L 2924/3025; H01L 2924/3511

(57) ABSTRACT

A package which includes an inorganic carrier body having a cavity, an organic Integrated circuit substrate embedded in the cavity of the carrier body, and a redistribution structure formed partially on and/or above the carrier body and partially on and/or in the integrated circuit substrate.

### CROSS-REFERENCE TO RELATED APPLICATIONS

This application is a national stage application, filed under 35U.S.C. § 371, of International Patent Application No. PCT/EP2023/051887,filed on Jan. 26, 2023, claiming priority of the Chinese Patent Application No. CN 202210107360.6, filed on Jan. 28, 2022, the disclosures of which are hereby incorporated by reference herein in their entirety.

### TECHNICAL FIELD

The disclosure relates to a package and to a method of manufacturing the package.

### TECHNOLOGICAL BACKGROUND

In the context of growing product functionalities of component carriers equipped with one or more components and increasing miniaturization of such components as well as a rising number of components to be connected to the component carriers such as printed circuit boards, increasingly more powerful array-like components or packages having several components are being employed, which have a plurality of contacts or connections, with ever smaller spacing between these contacts. In particular, component carriers shall be mechanically robust and electrically reliable so as to be operable even under harsh conditions.

Conventional approaches of forming component carrier-type packages are still challenging.

### SUMMARY

There may be a need to form a compact and reliable package. This need is met by the subject matter of the independent claims.

According to an exemplary embodiment of the disclosure, a package is provided which comprises an inorganic carrier body having a cavity, an organic integrated circuit substrate embedded in the cavity of the carrier body, and a redistribution structure formed partially on and/or above the carrier body and partially on and/or in the integrated circuit substrate.

According to another exemplary embodiment of the disclosure, a method of manufacturing a package is provided, wherein the method comprises providing an inorganic carrier body having a cavity, embedding an organic integrated circuit substrate in the cavity of the carrier body, and forming a redistribution structure partially on and/or above the carrier body and partially on and/or in the integrated circuit substrate.

### OVERVIEW OF EMBODIMENTS

In the context of the present application, the term “package” may particularly denote any support structure which is capable of accommodating one or more components thereon and/or therein for providing mechanical support and/or electrical connectivity. In other words, a package may be configured as a mechanical and/or electronic carrier for components. In particular, a package may be a component carrier-type device. Such a component carrier may be an IC (integrated circuit) substrate. A component carrier may also be a hybrid board combining different types of component carriers. A role of packaging is to house a component, supply it with electricity and act as an interface between the component and the rest of the elements in the system. Moreover, a function of a package may be to protect the component from dirt and physical impact and also fulfill thermal management requirements. A package may comprise one or more components, component carriers, a redistribution layer (RDL) structure, input and/or output elements, etc. Furthermore, advanced package technology may avoid performance limitations for components. Embodiments of the present disclosure may provide a technology to conform to a semiconductor package technology development trend and to meet even demanding performance requirements of packages from electricity transmission, thermal management, power management and environment protection with low effort.

In the context of the present application, the term “inorganic carrier body” may particularly denote a carrier structure of the package which comprises inorganic material. In particular, dielectric material of the inorganic carrier body or even the entire inorganic carrier body may be made exclusively or at least substantially exclusively from inorganic material. In another embodiment, the inorganic carrier body may comprise inorganic dielectric material and additionally another dielectric material and/or other inorganic material. An inorganic compound may be a chemical compound that lacks carbon-hydrogen bonds or a chemical compound that is not an organic compound. Examples of inorganic carrier body materials are glass (in particular silicon-based glass), a ceramic (such as aluminum nitride and/or aluminum oxide), and a material comprising a semiconductor (such as silicon oxide, silicon, silicon carbide, gallium nitride, etc.).

In the context of the present application, the term “integrated circuit substrate” (IC substrate) may particularly denote a component carrier having a size and a pitch adjusted to the requirements of an integrated circuit component (in particular a semiconductor chip) mounted thereon. An IC substrate may be a, in relation to a PCB, comparably small component carrier onto which one or more integrated circuit components may be mounted and that may act as a connection body between one or more chip(s) and a PCB. For instance, an IC substrate may have substantially the same size as an electronic component to be mounted thereon (for instance in case of a Chip Scale Package (CSP)). In another embodiment, the IC substrate may be larger than the assigned component (for instance in a flip chip ball grid array, FCBGA, configuration). More specifically, an IC substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the IC substrate and can be used to provide electrical, thermal and/or mechanical connections of housed components or unhoused components (such as bare dies), particularly of IC chips, with a printed circuit board or interposer. A dielectric part of an IC substrate may be composed of resin with reinforcing particles (such as reinforcing spheres, in particular glass spheres). A pitch, i.e. a distance between corresponding edges of two adjacent metal structures of an IC substrate may be not more than 120 μm, in particular not more than 100 μm. In contrast to this, a pitch of a PCB may be at least 200 μm, in particular at least 300 μm.

In the context of the present application, the term “cavity” may particularly denote a blind hole or a through hole in the inorganic carrier body shaped and dimensioned for accommodating an organic integrated circuit substrate entirely or partially therein.

In the context of the present application, the term “organic integrated circuit substrate” may particularly denote a block-, strip- or plate-shaped structure which comprises a dielectric material having an organic compound. In particular, dielectric material of the organic integrated circuit substrate may be made exclusively or at least substantially exclusively from organic material. In another embodiment, the organic integrated circuit substrate may comprise organic dielectric material and/or additionally another dielectric material. An organic compound may be a chemical compound that contains carbon-hydrogen bonds. For example, the organic integrated circuit substrate may comprise an organic resin material, an epoxy material, etc. In particular, integrated circuit (IC) substrate dielectrics may be dielectrics used for the organic integrated circuit substrate. Moreover, said organic integrated circuit substrate comprises additionally at least one electrically conductive vertical through connection and/or an electrically conductive horizontal connection.

In the context of the present application, the term “embedded” may particularly denote fully embedded or only partially embedded. In a fully embedded embodiment, the entire vertical spatial range between upper end and lower end of the organic integrated circuit substrate is located inside of the inorganic carrier body. In one embodiment, the upper end of the at least partially embedded organic integrated circuit substrate may be in alignment with an upper main surface of the inorganic carrier body and/or the lower end of the at least partially embedded organic integrated circuit substrate may be in alignment with a lower main surface of the inorganic carrier body. In another embodiment, the upper end of the at least partially embedded organic integrated circuit substrate may be located below an upper main surface of the inorganic carrier body and/or the lower end of the at least partially embedded organic integrated circuit substrate may be located above a lower main surface of the inorganic carrier body. However, it is also possible that an upper end portion of the organic integrated circuit substrate protrudes vertically beyond an upper main surface of the inorganic carrier body and/or that a lower end portion of the organic integrated circuit substrate protrudes vertically below an upper main surface of the inorganic carrier body.

In the context of the present application, the term “redistribution structure” may particularly denote a plurality of patterned electrically conductive layer structures in a dielectric matrix which have a portion with a smaller pitch as compared to another portion with a larger pitch. Pitch may denote a characteristic distance between adjacent electrically conductive structures, such as wiring elements or terminals. In particular, pitch may denote the distance between electrically conductive structures (such as pads or traces) of a semiconductor chip. By providing spatially separate regions with different pitch, a redistribution structure may be an electric interface between larger dimensioned electric connection structures (in particular relating to component carrier technology, more particularly printed circuit board technology or integrated circuit substrate technology) and smaller dimensioned electric connection structures (in particular relating to semiconductor chip technology, wherein a connectable component may be a semiconductor chip). In particular, a number of electrically conductive structures per area may be larger in a region with smaller pitch than in another region with larger pitch. A region with larger pitch may be arranged where the integrated circuit substrate is located, whereas another region with smaller pitch may be arranged at a periphery or an outer region of the package where a component is to be electrically connected. A function of the redistribution structure may be to rearrange the circuity and realize interconnection of two different densities of electric connection structures by providing the interface for different densities of electric connection structures. For example, the redistribution structure may be a redistribution layer (RDL).

In the context of the present application, the term “main surface” of a body may particularly denote one of two outermost (and in many cases largest)_opposing surfaces of the body. The main surfaces may be connected by circumferential side walls. The thickness of a stack, or another body having two opposing main surfaces, may be defined by the distance between the two opposing main surfaces.

According to an exemplary embodiment of the disclosure, a package is formed of an inorganic carrier body in which an organic integrated circuit substrate is embedded, wherein different portions of a redistribution structure are provided on and/or above the carrier body and on and/or in the integrated circuit substrate. Advantageously, an inorganic carrier body (preferably a glass body) may have very flat surfaces so that a planarization stage during processing may be dispensable and fine line processing thereon may be fully supported. Furthermore, an inorganic carrier body may have a high degree of thermal stability. Moreover, the inorganic carrier body has less coefficient of thermal expansion (CTE) mismatch with the component since both are more like inorganic material. Consequently, thermally caused undesired phenomena such as thermal stress, warpage and delamination will not impact the package significantly. Embedding an organic IC substrate in such an inorganic carrier body may provide a package being configured for surface mounting of a component (such as a semiconductor chip) on one main surface while the other main surface may be used for mounting the package on a mounting base (such as a printed circuit board). Highly advantageously, a redistribution structure on the component-side of the package may be contributed partially by the inorganic carrier body and partially by the organic integrated circuit substrate. Hence, a hybrid redistribution structure may be created which may support connections with many input/output terminals of a component while being perfectly compatible with a miniaturized design. Hence, both the inorganic carrier body and the organic IC substrate may contribute to a transition of electric connection structures from smaller characteristic dimensions and distances at the component side to larger characteristic dimensions and distances at an opposing other side of the package. Embedding the organic integrated circuit substrate in the cavity of the carrier body may suppress warpage and/or enhance mechanical stability of the organic integrated circuit substrate. Moreover, substrate warpage may be suppressed by redistributing stress when embedding.

Since the IC substrate is connected with the inorganic carrier body, the rigidity of the inorganic carrier body provides mechanical stability for the IC substrate as well. Furthermore, the inorganic carrier body may provide a power delivery functionality and may interconnect to top and bottom build-up layers. Furthermore, the symmetric structure with the inorganic carrier body and the organic IC substrate may improve the warpage behavior, in particular can contribute to mitigate warpage of the substrate by stressing balance between top and bottom.

Moreover, the integration of a redistribution structure to extend over both the inorganic carrier body and the organic IC substrate can also enhance stability and rigidity and may improve the whole package's warpage behavior to thereby allow for an asymmetric final structure without issues. As the organic material in the IC substrate is likely to change (like shape change, warpage and/or shrinkage) through processing with different condition and/or in the environment, the glass carrier with its stiffness may help and support the IC substrate's resistance to change when the IC substrate is embedded in the glass carrier. With the redistribution layer extending to the glass carrier from the IC substrate, it may help to keep the dimension (to avoid the shrinkage) and provide a flat, stable, and big mounting base with very fine line structuring for high end applications. Thus, the glass carrier surface may enhance the fine line structure formation. In general, a redistribution layer connected to a component (such as a semiconductor chip) may have finer structures than the IC substrate under the redistribution structure. Warpage behavior may also depend on the ratio of integrated circuit substrate and inorganic carrier body structure. Since appropriate inorganic materials, such as glass, may be highly stable during a thermal change, the overall package structure may enhance the warpage management. Even more important, stress balance during a thermal change may be significantly improved as generally an inorganic carrier may show less change under temperature change and may be stiffer than an organic substrate. In case the total package behavior is governed by the organic substrate at a certain temperature, a smaller organic substrate at the same package size may give less impact on total package behavior. Additionally, it is also beneficial for the fine line structuring.

In the following, further exemplary embodiments of the package and the method will be explained.

Vias and other electrically conductive layer structures of the redistribution structure and/or of the inorganic carrier body may define a different integration density with respect to those in the integrated circuit substrate. The term “integration density” may denote a number of electrically conductive structures per area or volume of the respective region of the package. In particular, the number of contacts (including pads) per area on the redistribution structure may be higher than the number of the contacts (including pads) per area on IC substrate and/or on the inorganic carrier body. Thus, integration density may mean a quantity of electrically conductive structures (such as traces, pads, vias and bumps) per mm². The integration density in the IC substrate and/or in the inorganic carrier body can be less than the integration density in the redistribution structure, and correspondingly the line space ratio may be different. Since PCB and IC substrate technology may be based on larger electrically conductive structures than semiconductor technology (according to which a component connected with the redistribution structure may be formed), the mentioned design rule may be appropriate for bridging the two combined technologies.

For example, the layer count of the redistribution structure may be in a range from 1 layer to 10 layers, in particular in a range from 1 layer to 5 layers. A via size in the redistribution structure may be less than 20 μm, in particular less than 10 μm. Trace width and space in the redistribution structure may be less than 5 μm/5 μm, in particular less than 2 μm/2 μm. A bump pitch may be less than 40 μm, a bump size may be less than 20 μm. What concerns dielectric material of the redistribution structure, it may be liquid-type (such as photoimageable dielectric, polyimide, etc.) or film-type (such as Ajinomoto build-up film (ABF) material).

The integrated circuit substrate may comprise a ball grid array interface with trace width/space of 9 μm/12 μm. It is also possible that the integrated circuit substrate has a fine line width/space of for example 5 μm/5μm. However, an exemplary embodiment of the disclosure relates to a package which can have a redistribution structure with very fine line structure with high integration density and a normal substrate with less integration density. This may simplify the manufacture while allowing a high yield of the final packages. However, if a high integration density is desired for the embedded IC substrate, it is for instance possible to reduce the layer count of the redistribution layer.

In an embodiment, part of the redistribution structure extends into the cavity. Thus, the redistribution structure may have a pronounced extension in a vertical direction and may extend partially inside of the cavity and partially vertically and laterally beyond the cavity.

In an embodiment, the redistribution structure has a larger vertical extension on and/or in the integrated circuit substrate than on and/or above the carrier body. Thus, the redistribution structure may be configured to spatially extend upwardly and laterally. For instance, the redistribution structure may have a substantially stepped (for example substantially T-shaped) configuration extending upwardly or may taper upwardly. Hence, the redistribution structure may be horizontally more confined where extending from the organic integrated substrate and may widen towards a component mounting surface of the package. This may combine a compact design with a large component mounting area.

In an embodiment, at least one layer structure of the redistribution structure is formed only on and/or in the integrated circuit substrate without extending to the carrier body. In particular in a bottom portion of the redistribution structure, the redistribution structure may be connected with the integrated circuit substrate only, but not with the inorganic carrier body. In a top portion of the redistribution structure, the redistribution structure may then extend over both the integrated circuit substrate and the inorganic carrier body. Such a design may keep construction of the inorganic carrier body simple.

In an embodiment, at least one layer structure of the redistribution structure is formed on and/or above the carrier body and on and/or above the integrated circuit substrate. Hence, at least one planar electrically conductive layer structure (for instance a patterned metal layer) may extend over both the inorganic carrier body and the organic IC substrate. This may provide a large mounting area for one or more components being surface mounted on top of the redistribution structure. At the same time, such a planar electrically conductive layer structure can be processed in common what concerns the region of the inorganic carrier body and of the organic integrated circuit substrate. This keeps the manufacturing process simple and fast.

In an embodiment, at least one layer structure of the redistribution structure is formed as an integral part of the integrated circuit substrate. In other words, part of the redistribution structure may be integrally formed with the integrated circuit substrate, for instance as one or more top layer structures thereof. Also, this measure contributes to a compact design of the package and promotes a simple manufacturing process.

In an embodiment, an exterior surface of the redistribution structure is planar. In particular, the upper main surface of the package may be defined by the planar exterior surface of the redistribution structure. This planar exterior surface may be used for surface mounting one or more electronic components thereon, such as semiconductor chips, in direct connection with the redistribution structure. This keeps electric connection paths short which may lead to small ohmic losses and high signal integrity.

In an embodiment, an interior surface of the redistribution structure is profiled. Said interior surface of the redistribution structure may be the lower interface between the redistribution structure on the one hand and the inorganic carrier body and the organic integrated circuit substrate on the other hand. At that interface, the redistribution structure may have a stepped configuration, for example due to its extension deeper towards or into the organic integrated circuit substrate as compared with the inorganic carrier body. Such a design may focus or concentrate electrically conductive structures from a larger horizontal extension in a higher integration density region at an exterior surface of the package towards a lower integration density region at an interface of the redistribution structure to the IC substrate. At the exterior surface of the package, this may support a high connection area for one or more components with high integration density in line with even demanding requirements of modern semiconductor technology. In an interior of the package, the electric connections may be focused or spatially concentrated towards a central portion of the package only, i.e. to a lateral extension of the organic IC substrate. This may render it dispensable to provide electric through connections also in the inorganic carrier body. Advantageously, construction of the inorganic carrier body may then be very simple.

In an embodiment, the inorganic carrier body comprises glass, ceramic, a semiconductor, metal, etc. Optionally, the inorganic carrier body may also comprise, as an additional constituent, organic carriers (such as carbon composite, aramid composite). Also, highly rigid functional materials may form part of the inorganic carrier body.

It may however be preferred that the inorganic carrier body consists only of glass or comprises glass. Glass as the main or only material of the inorganic carrier body has significant advantages: On the one hand, a glass carrier body may be provided with an extremely flat and smooth surface so that fine line structuring of a portion of the redistribution structure on the glass carrier body may be possible. No planarization of a glass carrier is necessary before integrating it into the package. Apart from this, glass is highly robust against temperature changes with good thermal conductivity and thereby mechanically stabilizes the entire package. The pronounced temperature stability and the very smooth surface of a glass carrier body allow the manufacture of packages with high yield. Furthermore, glass is also scalable to support a large size body of a panel level package which can increase the throughput compared with other kinds of inorganic material with similar property such as silicon. With its low Dk, Df, glass can be a good dielectric material which meets the requirement of high-performance computing for achieving good electrical performance with low loss and high signal integrity.

In an embodiment, at least one main surface of the integrated circuit substrate comprises electrically conductive connection bumps but no wiring lines. In other words, no electrically conductive traces need to be provided at one or both main surfaces of the IC substrate. Only bumps or pads of metallic material, or other metallic structures, need to be provided at such a main surface. This simplifies the manufacturing process of the IC substrate and of the package as a whole.

In an embodiment, the inorganic carrier body is free of interior electrically conductive connection structures. For example, the inorganic carrier body may consist only of electrically insulating material, such as glass. By omitting electrically conductive connection structures in the inorganic carrier body, provision of the inorganic carrier body can be possible with very low effort. No processing thereof may be necessary. In such an embodiment, the entire electricity (what concerns electric signals and electric power) may be guided through the IC substrate, whereas the inorganic carrier body may then be electrically passive. Corresponding embodiments are shown, for example, in FIG. 3 and FIG. 4.

In another embodiment, the package comprises at least one electrically conductive connection structure in an interior of the inorganic carrier body. For instance, such an electrically conductive connection structure may be a vertical through connection (see for example FIG. 1). Such an electrically conductive vertical through connection may particularly denote one or more vertically extending metallic structures, for example comprising or consisting of copper. Examples for an electrically conductive vertical through connection may be a metal pillar and/or metal bump (in particular a copper pillar), a metal cylinder, a metal-filled drill hole (such as a plated laser via or a plated mechanically drilled via), an array of vertically stacked vias, or a stacked via-pad sequence. In one embodiment, all electrically conductive elements of the organic carrier body may be vertical through connections. However, in an embodiment, the at least one organic carrier body may additionally comprise one or more horizontal electric connection elements. A corresponding horizontal electric connection element may be located at a surface of the inorganic carrier body and/or in an interior of the inorganic carrier body.

In an embodiment, a surface roughness Ra of the inorganic carrier body is not more than 100 nm, in particular not more than 50 nm. Said surface roughness Ra may be in particular present at a surface area of the inorganic carrier body to which a portion of the redistribution structure is applied. Such a low roughness Ra may ensure that electrically conductive layer structures may be formed on this surface of the inorganic carrier body with highest spatial accuracy. Furthermore, a low roughness can improve the electrical transmission performance (low loss, high signal integrity). Thus, the described embodiment may be particularly appropriate for high density integration (HDI) applications and/or for fine line patterning.

In an embodiment, the package comprises an additional layer build-up on a side of the carrier body and of the integrated circuit substrate which opposes the redistribution structure. In particular, the package may comprise an additional layer build-up in the form of a laminated layer stack on its bottom side. Such a laminated layer stack may be formed of one or more electrically insulating layer structures (such as prepreg sheets) and one or more electrically conductive layer structures (such as copper vias and/or traces and/or patterned copper foils or layers). The inorganic carrier body with one or more integrated circuit substrates may form a robust mechanical base or support and may electrically connect to the bottom-sided laminated layer stack.

In an embodiment, the layer build-up and the redistribution structure are asymmetric, in particular have different thicknesses. The high stability of the package thanks to the provision of the inorganic carrier body (preferably made of glass) may make it possible that a construction of the package in a vertical direction shows a deviation from a symmetric configuration. As a result, a high integration density at a component mounting side of the package may be combined with a high freedom of designing the opposing main surface of the package without the risk of undesired phenomena such as warpage or delamination.

In an embodiment, the redistribution structure has a higher integration density than the layer build-up of the stack. Thus, the side of the package relating to the redistribution structure may provide a mounting area for mounting one or a plurality of electronic components such as semiconductor chips. At the same time, the side of the package relating to the layer build-up may be configured for connecting the package at said surface with a mounting base, such as a printed circuit board.

In an embodiment, the integrated circuit substrate comprises a laminated layer stack comprising at least one electrically conductive layer structure and at least one electrically insulating layer structure. In the context of the present application, the term “stack” may particularly denote an arrangement of multiple planar layer structures which are mounted in parallel on top of one another. Furthermore, the term “layer structure” may particularly denote a continuous layer, a patterned layer or a plurality of non-consecutive islands within a common plane. Lamination may be carried out by applying pressure and/or heat. The IC substrate may in particular be a component carrier with small-dimensioned structures.

In an embodiment, the package comprises a dielectric filling medium covering at least part of at least one vertical sidewall and/or at least part of at least one horizontal wall of the carrier body and/or of the integrated circuit substrate. Such a dielectric filling medium may spatially separate the carrier body with respect to the redistribution structure. When embedding the organic IC substrate into the inorganic carrier body, the inorganic carrier body may be placed in a cavity formed in the inorganic carrier body. Thereafter, gaps between the inorganic carrier body and the organic IC substrate may be filled partially or entirely by a dielectric filling medium. For instance, said dielectric filling medium may comprise a glue which can be filled in between the inorganic carrier body and the organic IC substrate and which may then be cured. It is also possible that such a dielectric filling medium originates from one or more dielectric sheets (such as prepreg sheets or resin sheets) attached to the inorganic carrier body and the organic integrated circuit substrate and being cured by lamination, i.e. the application of heat and/or pressure. During curing, resin from such dielectric sheets may flow in the gaps and may adhere to the organic IC substrate in place inside of the cavity of the inorganic carrier body.

In an embodiment, the dielectric filling medium comprises a low Young modulus dielectric, in particular having a value of the Young modulus of not more than 5 GPa. Hence, the dielectric filling medium may be a mechanically soft material which may function as a buffer for buffering stress between the organic integrated circuit substrate and the inorganic carrier body. Thus, the provision of a low Young modulus dielectric filling medium between the organic integrated circuit substrate and the inorganic carrier body may significantly increase the robustness of constituents of the package against failure, in particular thermally-caused failure. Furthermore, the filling medium can also function for heat dissipation.

In an embodiment, the package comprises one or more electronic components being surface mounted on the redistribution structure. In the context of the present application, the term “electronic component” may particularly denote a member fulfilling an electronic task. Such an electronic component may be an active component such as a semiconductor chip comprising a semiconductor material, in particular as a primary or basic material. The semiconductor material may for instance be a type IV semiconductor such as silicon or germanium or may be a type III-V semiconductor material such as gallium arsenide. In particular, the semiconductor component may be a semiconductor chip such as a bare die or a molded die. A bare die may be a non-encapsulated (in particular non-molded) piece of semiconductor material (such as silicon) having at least one monolithically integrated circuit element (such as a diode or a transistor). Moreover, semiconductor materials suitable for photonic packages are also possible. For example, an electronic component to be surface mounted on the package may be a HBM (high-bandwidth memory) or a silicon interposer. It is also possible to surface mount a plurality of integrated circuit components on an integrated circuit component mounting side of the redistribution structure.

In an embodiment, the inorganic carrier body has a further cavity. The package may comprise a further organic integrated circuit substrate embedded in the further cavity of the carrier body. In such an embodiment, the redistribution structure may be formed partially on and/or in the further integrated circuit substrate, in particular part of the redistribution structure may extend into the further cavity. In such an embodiment, at least two integrated circuit substrates in combination with a common inorganic carrier body share a preferably continuous redistribution structure. Hence, even sophisticated electronic functionality may be realized with such a design.

In an embodiment, the package comprises an electronic component mounted on the redistribution structure above the integrated circuit substrate, and a further electronic component mounted on the redistribution structure above the further integrated circuit substrate. Thus, a respective electronic component may be assigned to each of the integrated circuit substrates of a common package. A respective electronic component may extend over a portion of the redistribution structure relating to an assigned IC substrate. It is also possible that said electronic component extends partially over a portion of the inorganic carrier body. Thus, a high mechanical stability and alignment accuracy may be combined with a reliable electric connection of an electronic component.

For example, the electronic component and the further electronic component may functionally cooperate, for instance may exchange electric signals. In one embodiment, the electronic component is a processor and the further electronic component is a memory chip. In another embodiment, the electronic component is a control chip and the further electronic component is a sensor chip controlled by the control chip. In still another embodiment, the electronic component is an optical chip and the further electronic component is an assigned electric chip. The electronic component can be an RFIC (radio-frequency integrated circuit), and/or a chiplet for heterogeneous packaging.

In an embodiment, the integrated circuit substrate and the further integrated circuit substrate are configured for providing different functions. The IC substrate and the further IC substrate may also collaborate functionally and may be electrically coupled with each other for this purpose.

In an embodiment, the package comprises an electronic component and a further electronic component mounted on the redistribution structure which is configured as a bridge between the electronic component and the further electronic component. By configuring part of the redistribution structure so as to provide a bridge function and so as to electrically couple the surface mounted electronic component and the further electronic component with each other, the handling of separate component connecting members (such as bridge dies or interposer inlays) may be dispensable. The component can also be a chiplet (such as a plurality of small chips with different modules combined as one big chip to function, for example, like a central processing unit (CPU) or like a graphical processing unit (GPU)). The chiplet can be placed on the same surface or it can be stacked with each other as a three-dimensional package.

In an embodiment, the integrated circuit substrate is configured for providing a voltage regulation function (in particular a function of regulating electric voltage levels in the package), a heat management function (in particular for removing heat generated during operation from an interior of the package and/or for controlling one or more heat removal paths inside of the package), a power supply function (in particular for controlling the supply of electric power to one or more members of the package, for instance to one or more surface mounted and/or embedded components), a high-frequency application function (for instance an RF (radio frequency) transmitter and/or receiver function), a signal processing function (for instance a conversion of an electric signal into an optical signal, or vice versa) and/or an amplifier function (for instance for amplifying or attenuating an electric signal). For this purpose, it may also be possible that at least one further electronic component (in particular at least one further semiconductor chip) is embedded in the integrated circuit substrate for providing or contributing to the respective function.

In an embodiment, the package comprises an optical communication path extending through the carrier body. For instance, an optical waveguide may be guided through the package, for example vertically through the inorganic carrier body, for carrying an optical signal. It may also be possible that the package comprises an optical chip equipping the package with an optical or optoelectronic functionality. In particular, such an optical chip may be a chip configured for receiving an optical signal, and more particularly for converting the received optical signal into an electric signal by an electro-optical converter (such as a photodiode). The optical chip may also have processing capability for processing an optical signal and/or an electric signal to or from which the optical signal can be derived by the optical chip. The optical chip may be an electro-optical chip, in particular providing an optical functionality of an electro-optical system. In particular, the optical chip may also have an integrated semiconductor laser diode and/or an amplifier. Hence, examples of integrated circuit elements of an optical chip may be a photodiode and/or a laser diode. For instance, integrated group III-V devices may be implemented in the optical chip, for example as at least one laser, at least one amplifier and/or at least one photodiode.

In an embodiment, the redistribution structure has a first region with a first pitch and a second region with a second pitch, in particular a larger pitch, compared with the first pitch. Consequently, the first region may be a higher density connection region, whereas the second region may be a lower density connection region. For instance, the higher density connection region may be a region at an interface between the redistribution structure and at least one surface mounted component. In contrast to this, the lower density connection region may be a region at an interface between the redistribution structure and at least one of the inorganic carrier body and the organic integrated circuit substrate. The term “line pitch” may denote the trace space between two traces. With the described design rule in terms of line pitch, the lower density connection region may be manufactured in a comparably simple way. In order to match with more demanding line pitch properties of the surface mounted component(s), the higher density connection region may have a value of the line pitch smaller than that of the lower density connection region. This combines a reasonable manufacturing effort with reliable electric coupling and with excellent manufacturing effort balance and control. For example, the redistribution structure may have a pitch above the carrier body differing from another pitch, in particular a larger pitch, in the integrated circuit substrate.

In an embodiment, at least part of the carrier body is coated with a functional coating. In the context of the present application, the term “functional coating” may particularly denote formation of a thin layer structure covering at least part of the carrier body and being configured to provide a specific function to the package. In other words, the package may be functionally extended when being provided with the functional coating or film, which function is not available if the functional coating or film is missing. Examples of the function are a prolongation of a lifetime of the package or parts thereof, a reduction of the interior mechanically and/or thermal stress, a mechanical buffer function, etc. For instance, said functional coating is configured for promoting adhesion between the carrier body and its surroundings in the package. It is also possible that the functional coating is configured for providing a fatigue protection to the carrier body. Additionally or alternatively, it is possible that said functional coating is configured for reducing a CTE (coefficient of thermal expansion) mismatch between the carrier body and its surroundings in the package. Furthermore, it may be possible that said functional film is configured for distributing stress within the package. In yet another example, said functional coating is configured for removing heat and/or spreading heat generated by at least one component of the package. In still another embodiment, said functional film is configured for shielding electromagnetic radiation (in particular high-frequency radiation) between components of the package and/or between an exterior of the package and a component of the package. In yet another embodiment, the functional coating may be made of a low loss material having low loss for high frequencies.

In an embodiment, the package comprises at least one capacitor formed on the carrier body and/or embedded in the integrated circuit substrate. One or more surface mounted or embedded passive components embodied as capacitor components may accomplish for example a power delivery function. By providing the at least one capacitor on the carrier body or embedded in the IC substrate, power delivery may occur spatially close to one or more surface mounted components. Optimizing a power delivery network (PDN) design has been more and more important with the advance of high performance and low power system on chip (SOC) to integrate more functions in a semiconductor integrated circuit (IC). A skilled person will appreciate that a PDN design impacts the minimum power supply voltage for a processor's proper operation with high clock frequency. In general, a PDN can be designed, improved, and optimized by accurate PDN modeling, proper and enhanced capacitive decoupling, appropriate co-design, and in the provision of a DC power supply like power management integrated circuit (PMIC) including a DC-DC converter.

In an embodiment, an exterior interface area of the package facing away from the redistribution structure may be configured as a grid array interface, for instance as a ball grid array interface or a land grid array interface. Land Grid Array (LGA) and Ball Grid Gray (BGA) are both Surface Mount Technologies (SMT), in particular for printed circuit boards or motherboards. These array interfaces basically define how the package will actually be mounted, in particular on a PCB or a motherboard's socket. Essentially, the most basic difference between the two is that an LGA based package can be plugged in and out of the PCB or motherboard and can also be replaced. A BGA based package, however, may be soldered on the PCB or motherboard and thus cannot be plugged out or replaced. A Ball Grid Array, on the other hand, may have spherical contacts which are then soldered onto the PCB or motherboard. An LGA type package may be placed on top of a socket on a PCB or motherboard. In this context, the package may have flat surface contacts whereas the PCB or motherboard socket may have pins.

In an embodiment, the IC substrate may be shaped as a plate. This contributes to the compact design, wherein the IC substrate nevertheless provides a proper basis for mounting components thereon. Furthermore, in particular a bare die as an example for an electronic component, can be conveniently embedded, thanks to its small thickness, into a thin plate-type IC substrate.

The IC substrate may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide, polybenzoxazole, BCB (Benzocyclobutene), or PBO (Poly (p-phenylen-2,6-benzobisoxazol).

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (for instance based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres, or other kinds of filler particles, for example made of glass (multilayer glass) in order to form a composite, could be used as well. A semi-cured resin in combination with a reinforcing agent, for instance fibers impregnated with the above-mentioned resins is called prepreg. These prepregs are often named after their properties for instance FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high-frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the IC substrate as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supra-conductive material or conductive polymers, such as graphene or poly (3,4-ethylenedioxythiophene) (PEDOT), respectively.

At least one further component may be embedded in and/or surface mounted on the respective stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al²O³) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in, or surface mounted on, the IC substrate. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate or an interposer, for example in a board-in-board configuration. The component may be surface mounted on the IC substrate and/or may be embedded in an interior thereof. Moreover, other components, in particular those which generate and emit electromagnetic radiation and/or are sensitive with regard to electromagnetic radiation propagating from an environment, may be used as a component.

In an embodiment, the IC substrate is a laminate. In such an embodiment, the IC substrate is a compound of multiple layer structures which are stacked and connected together by applying a pressing force and/or heat.

After processing interior layer structures of the IC substrate, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or IC substrate.

In particular, an electrically insulating solder resist may be applied to one or both opposing main surfaces of the layer stack or IC substrate in terms of surface treatment. For instance, it is possible to form such a solder resist on an entire main surface and to subsequently pattern the layer of solder resist so as to expose one or more electrically conductive surface portions which shall be used for electrically coupling the IC substrate to an electronic periphery. The surface portions of the IC substrate remaining covered with solder resist may be efficiently protected against oxidation or corrosion, in particular surface portions containing copper.

It is also possible to apply a surface finish selectively to exposed electrically conductive surface portions of the IC substrate in terms of surface treatment. Such a surface finish may be an electrically conductive cover material on exposed electrically conductive layer structures (such as pads, conductive tracks, etc., in particular comprising or consisting of copper) on a surface of an IC substrate. If such exposed electrically conductive layer structures are left unprotected, then the exposed electrically conductive IC substrate material (in particular copper) might oxidize, making the IC substrate less reliable. A surface finish may then be formed for instance as an interface between a surface mounted component and the IC substrate. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1 illustrates a cross-sectional view of a package according to an exemplary embodiment of the disclosure.

FIG. 2 illustrates a preform of a package according to an exemplary embodiment of the disclosure.

FIG. 3 illustrates a cross-sectional view of a package according to another exemplary embodiment of the disclosure.

FIG. 4 illustrates a cross-sectional view of a package according to still another exemplary embodiment of the disclosure.

FIG. 5, FIG. 6, FIG. 7, FIG. 8, FIG. 9, and FIG. 10 illustrate cross-sectional views of structures obtained during carrying out a method of manufacturing a package, shown in FIG. 10, according to an exemplary embodiment of the disclosure.

FIG. 11 illustrates a cross-sectional view of a package according to another exemplary embodiment of the disclosure.

FIG. 12 illustrates a preform of a package according to an exemplary embodiment of the disclosure.

### DETAILED DESCRIPTION OF ILLUSTRATED EMBODIMENTS

The illustrations in the drawings are schematically presented. In different drawings, similar or identical elements are provided with the same reference signs.

Before referring to the drawings, exemplary embodiments will be described in further detail, some basic considerations will be summarized based on which exemplary embodiments of the disclosure have been developed.

Fan-out packaging can be denoted as the formation of any package with connections fanned-out of a chip surface. Fan-out packaging has been traditionally considered for wafer-level package technology. More recently, fan-out panel-level packaging has been considered as a low-cost process and high throughput concept compared to wafer-level packaging. Fan-out packaging is very dynamically evolving with many new technology formats (such as standard redistribution structures used in a die embedded PCB or silicon, fan-out organic interposers, and fan-out redistribution structures on substrate using PCB panel technology). When a redistribution structure on a die embedded structure is compatible with standard wafer-level or panel-level packaging, then the package is competitive. Also, it can help to solve manufacturing issues like high manufacturing effort, warpage from asymmetric structuring, etc. Panel packaging may reduce the high-volume manufacturing cost, as the wafer-level package is more expensive with lower throughput, costly material and machine. However, panel packaging is likely to encounter warpage issues. That is why embodiments of the disclosure introduce an inorganic carrier to provide stiffness. In other approaches, developers are expecting that key advantages from fan-out redistribution structure interposer technology can be low-latency chip to chip communication, high-bandwidth density, reasonable manufacturing efforts, low thermal resistance, less vertical interconnection loss for signal integrity, and design flexibility what concerns line width/space. Combining higher density substrate technology with lower density module technology is a further new concept.

According to an exemplary embodiment of the disclosure, a package is provided which has an inorganic carrier body (such as a glass block) and an organic IC substrate embedded in an opening of the inorganic carrier body. Advantageously, a redistribution structure is formed partially at the carrier body and partially at the IC substrate. Such a hybrid redistribution structure may efficiently couple a top-sided surface mounted electronic component (such as a semiconductor chip) with a bottom-sided mounting base (for instance a PCB) beneath the package. The hybrid redistribution structure may ensure a compact design and low signal and energy losses in view of the short electric paths in particular in a vertical direction.

According to an exemplary embodiment of the disclosure, an IC substrate may be embedded into an inorganic carrier body (preferably a glass cavity core). A hybrid redistribution structure may be formed partially on and/or in the IC substrate and partially on and/or above the inorganic carrier body. In particular, an FCBGA-type IC substrate may be embedded in a cavity in a glass panel. A redistribution structure may be formed on a hybrid substrate core. In particular, it may be possible to implement a plurality of IC substrates on one package and/or a plurality of electronic components on a hybrid substrate assembly on a redistribution structure at once. A package according to an exemplary embodiment of the invention may be in particular applicable to heterogeneous packaging architectures. Advantageously, exemplary embodiments of the disclosure may make it possible to combine a fine-line redistribution structure together with an IC substrate. The rigidity of the IC substrate may be improved by embedding it into an inorganic carrier body, such as a glass carrier. This may be helpful to reduce warpage and enhance flatness of the package. The packaging architecture according to an exemplary embodiment of the disclosure is properly compatible with a high input/output (I/O) Ball Grid Array architecture. Advantageously, an exemplary embodiment of the disclosure may establish a chip-to-chip connection via a portion of the redistribution structure to thereby provide the function of a bridge. In particular, the IC substrate of the package may be functionalized to provide an additional function, such as voltage regulation, heat management, power supply, etc.

In an embodiment, the inorganic carrier body may be made of carbon material instead of glass in order to achieve an even better thermal management. Also, other kinds of materials may be possible for the inorganic carrier body. In another embodiment, it may also be possible to implement different types of IC substrates (for instance IC substrates providing different functions) in different cavities (such as air cavities for high-frequency, power, signal, amplifier applications) of an inorganic carrier body of a package. Furthermore, the IC substrate can be not only provided with part of a redistribution structure, but it can also be embodied as a coarse structure. For example, it may also be possible that the redistribution structure is configured for fine line structuring only on the region of the inorganic carrier body (for instance in a glass area). In an embodiment, a respective IC substrate may be embedded in each cavity of the inorganic carrier body. This may or may not be done in the context of ultra-fine line routing layers on a surface. Advantageously, glass may be used as a highly appropriate material of the inorganic carrier body not only for functioning as a stiffener, but it may also be possible to provide one or more optical paths in the glass. Electric circuits may be embedded in the IC substrate.

In an embodiment, different pitches may be formed on the redistribution structure above the IC substrate and above glass material of the inorganic carrier body. Advantageously, the pronounced flatness of glass may permit the formation thereon of electrically conductive layer structures with more demanding line/space characteristics. Furthermore, it may be possible to connect one or more further IC substrates (for example using one or more bumps, vias, etc.) Glass material of the inorganic carrier body may also be provided with one or more holes which may be filled with an appropriate material, such as copper. In particular, it may be possible to cover (for instance coat) glass with chromium, titanium (for instance for using the package even under harsh conditions) and/or tungsten which may be structured afterwards (this may mitigate potential shortcomings of glass such as the tendency of crack formation). For example, chromium can be applied on the glass, and a channel may be provided to cool down (for instance by forming at least one via filled with copper). Also, an entity for power supply may be foreseen. Furthermore, a relation between a glass thickness and a distance between different cavities in an inorganic carrier body may be considered. It may be possible to define the function of chips connected with different domains. A used filling material can be of low Young modulus type to balance a mismatch (for example to compensate a CTE (coefficient of thermal expansion) mismatch between encapsulation and glass. Such an approach may be executed with different appropriate kinds of material. The CTE mismatch can be also balanced at least partially by choosing an appropriate glass type for ABF or molding material filling. Furthermore, it can be considered that the thickness of glass may be correlated with the thickness of layers of the redistribution structure. In an embodiment, it may be possible to coat glass of the inorganic carrier body with a thermally conductive material, for instance having a thermal conductivity of at least 10 W/mK.

It may also be possible to form one or more thin-film capacitors on glass of the inorganic carrier body to stabilize electric signals, a power supply, etc. For example, an integrated capacitor with glass may be implemented. Furthermore, it may be possible to implement one or more capacitors within the IC substrate to stabilize the power supply. For example, it may be possible to make trenches in the glass to embed one or more capacitors. However, it may also be possible to directly integrate one or more capacitors in a build-up for a power plane.

Briefly, an exemplary embodiment of the disclosure provides a hybrid redistribution structure partially relating to an IC substrate and partially relating to an inorganic carrier body and being configured for heterogeneous packaging. The IC substrate may be embedded in the (in particular glass carrier-type) inorganic carrier body, wherein the latter may provide a very flat surface highly suitable to build very fine lines of an interposer. Preferably, the thickness of the inorganic carrier body may be the same as the thickness of the organic IC substrate. The IC substrate may be encapsulated in a cavity of the inorganic carrier body, using a dielectric which may be for example a mold film, ABF or prepreg or paste. Redistribution layers of the redistribution structure may be built on at least one bonding layer of the inorganic carrier substrate and/or the organic IC substrate.

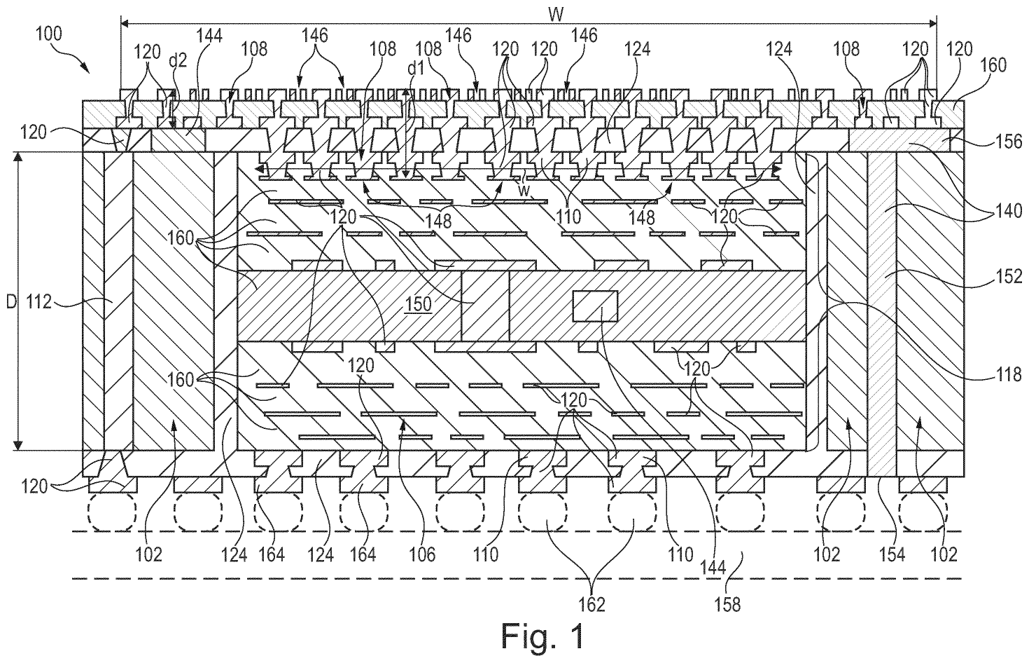

FIG. 1 illustrates a cross-sectional view of a package 100 according to an exemplary embodiment of the disclosure.

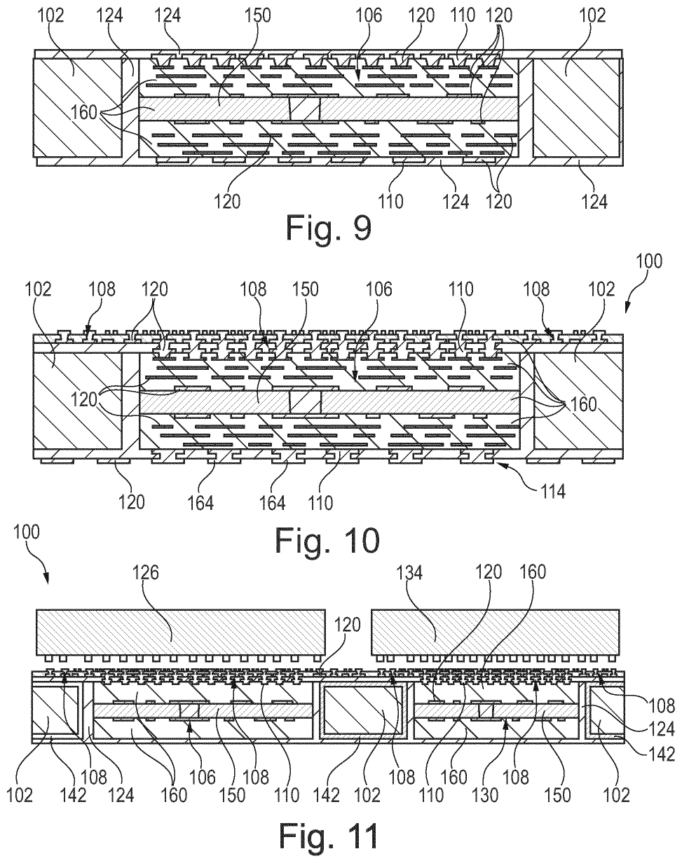

One or more electronic components (see reference signs 126, 134 in FIG. 3, FIG. 4 and FIG. 11) may be surface mounted on an upper main surface of the package 100 (not shown in FIG. 1).

On a bottom side of the package 100, a mounting base 158 can be provided on which the package 100 is mounted while establishing an electric connection in between. This may be accomplished by electrically conductive connection structures 162 between package 100 and mounting base 158, for instance solder balls or sinter structures. The bottom side of the package 100 may be provided with an electrically conductive pattern depending on a specific application. In the shown embodiment, a plurality of metallic (in particular copper) pads 164 are foreseen at the bottom main surface of the package 100 which may be electrically connected to the mounting base 158 by the electrically conductive connection structures 162. Additionally or alternatively, metal pillars (in particular copper pillars) may be provided as electrically conductive pattern on the lower main surface of the package 100 (not shown).

For example, the mounting base 158 may be a printed circuit board (PCB) or an interposer. Although not shown in FIG. 1, further components (such as further IC substrates, further (in particular molded) semiconductor chips, capacitors, inductors or other kind of components, etc.) may be assembled on the mounting base 158. The mounting base 158 can also be omitted in other embodiments.

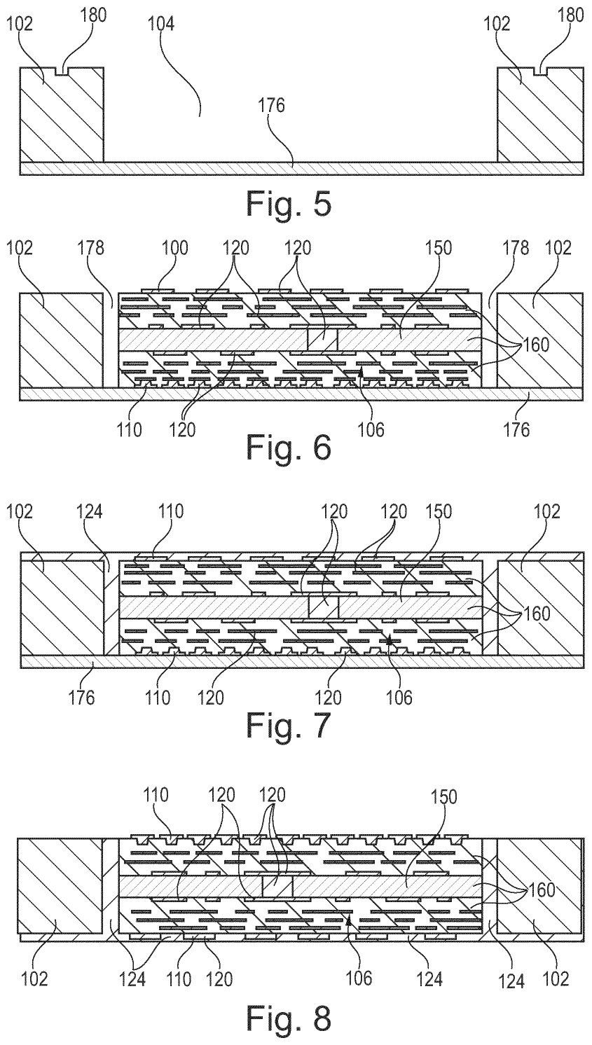

The illustrated package 100 comprises an inorganic carrier body 102 which can be formed based on a glass block with a central cavity (see reference sign 104 in FIG. 5). Glass is a highly appropriate material for the inorganic carrier body 102, since this material is very robust against temperature changes. Moreover, glass provides a high mechanical strength and is therefore very suitable for providing mechanical stability with stiffness to the package 100 as a whole. Beyond this, a glass block can be provided with a very smooth surface having a very small roughness Ra for example less than 100 nm. In particular at an upper horizontal main surface of the inorganic carrier body 102, a high degree of flatness may be achieved which may promote formation of electrically conductive layer structures 120 on and above the inorganic carrier body 102 with high spatial accuracy. In other words, the flat surface of the inorganic carrier body 102 is fully compatible with fine line structuring on top thereof. While glass may be a preferred material for the inorganic carrier body 102 for the above-mentioned reasons, the inorganic carrier body 102 may alternatively comprise for instance a ceramic. A portion of the inorganic carrier body 102 may also comprise metal (see the below described electrically conductive connection structure 112), and optionally one or more other materials. A portion of the inorganic carrier body 102 may also comprise magnetic paste around the conductive material to reduce a loss of electricity during electrical transmission due to the parasitic inductance.

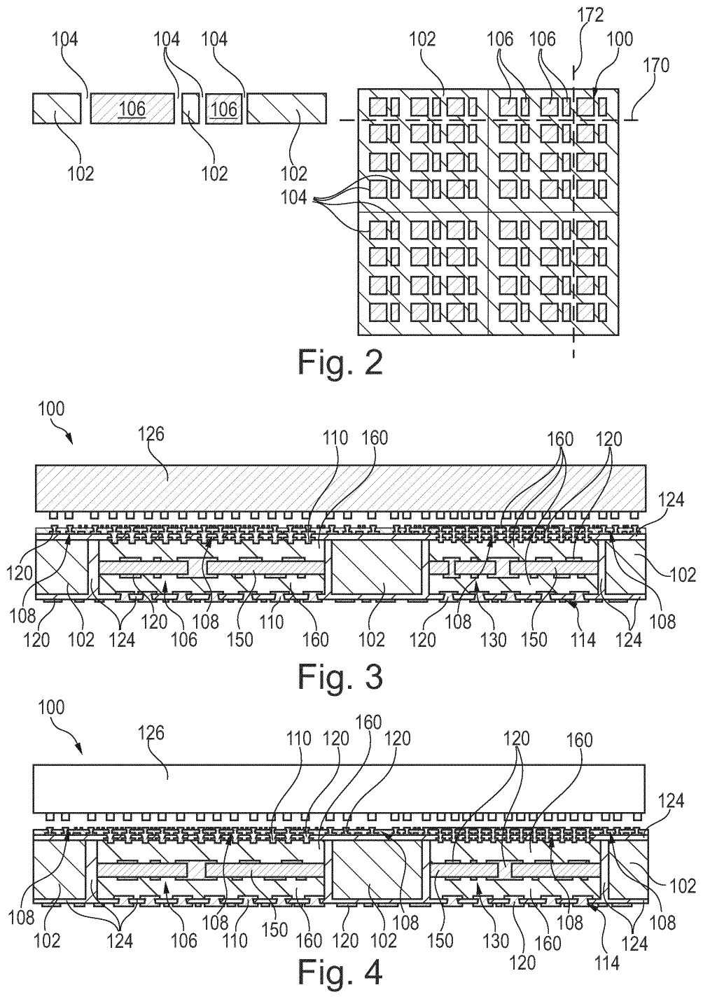

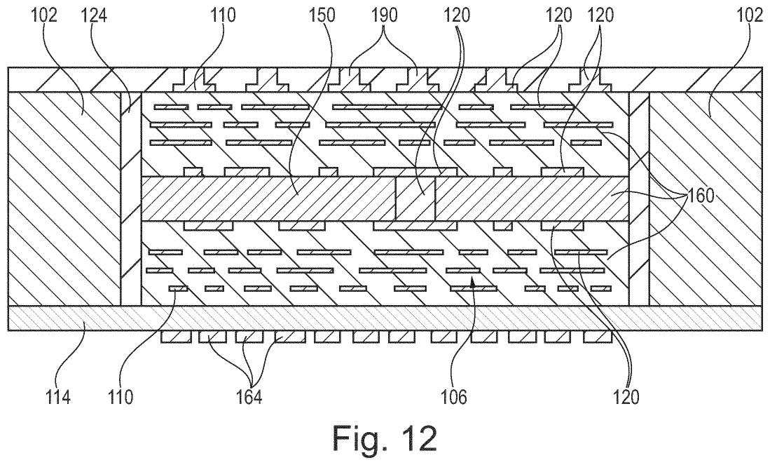

In embodiments (see for example FIG. 2, FIG. 3, FIG. 4, FIG. 5, FIG. 6, FIG. 7, FIG. 8, FIG. 9, and FIG. 10, FIG. 12), the inorganic carrier body 102 may be free of interior electrically conductive connection structures and may consist of glass only, which may keep the manufacturing process concerning the inorganic carrier body 102 very simple. In the embodiment of FIG. 1 however, the inorganic carrier body 102 may be equipped with one or more electrically conductive connection structures 112 (for example made of copper) in an interior of the glass body. In the illustrated embodiment, the electrically conductive connection structure 112 extends vertically through the entire thickness D of the inorganic carrier body 102 and may be for instance a metal filled via or a metal pillar. The vertical through connection in form of electrically conductive connection structure 112 may function for conducting electric signals and/or electric power and/or may promote cooling.

As shown as well in FIG. 1, the inorganic carrier body 102 may comprise an optical communication path 140 extending through the carrier body 102. For example, the optical communication path 140 may be formed by an optical waveguide 152, such as a glass fiber, extending vertically through the entire inorganic carrier body 102. One end of the optical waveguide 152 may for instance extend up to an exterior main surface 154 of the package 100, so that an optical signal (for instance in the form of a light beam) can be coupled into or out of the optical waveguide 152. An electro-optical converter component 156 embedded in the package 100 and optically coupled with the optical waveguide 152 may be configured for converting an optical signal into an electrical signal, or vice-versa.

As shown as well in FIG. 1, an organic integrated circuit substrate 106 is embedded in the cavity 104 of the carrier body 102. In the shown embodiment, the cavity 104 is formed by a through hole extending through the entire thickness D of the inorganic carrier body 102. The organic IC substrate 106 is inserted as an inlay into said through hole and is thereby embedded in the inorganic carrier body 102. Advantageously, the vertical thickness D of the inorganic carrier body 102 and of the organic IC substrate 106 may be the same. In view of the described and illustrated configuration in which the organic integrated circuit substrate 106 is embedded in the cavity 104 of the carrier body 102 with the same thickness D, a high mechanical stability of package 100 may be achieved. Advantageously, this may efficiently suppress warpage and may enhance mechanical stability of the organic integrated circuit substrate 106 and of the whole package 100. The configuration according to FIG. 1 may ensure that aligned continuous horizontal surfaces are provided at a top side and at a bottom side of an arrangement composed of the inorganic carrier body 102 and the organic IC substrate 102. In another embodiment, the mentioned thicknesses may also be different.

For example, the integrated circuit substrate 106 may comprise or consist of a laminated layer stack 118 comprising a plurality of electrically conductive layer structures 120 and electrically insulating layer structures 160. The electrically conductive layer structures 120 may comprise patterned copper layers which may form horizontal pads and/or a horizontal wiring structure. Additionally or alternatively, the electrically conductive layer structures 120 may comprise vertical through connections such as copper pillars and/or copper filled laser vias and/or other metallic structures. Moreover, the stack 118 of the integrated circuit substrate 106 may comprise one or more electrically insulating layer structures 160 (such as prepreg or resin sheets). In the shown embodiment, the stack 118 of the IC substrate 106 comprises a central core 150 (for instance made of fully cured resin with reinforcing particles, such as glass spheres, therein). On both opposing main surfaces of core 150, a respective layer build-up of electrically conductive layer structures 120 and electrically insulating layer structures 160 is formed for constructing IC substrate 106. Also surface finish (like ENIG or ENEPIG), a solder resist, etc. may be applied (not shown).

Advantageously, a redistribution structure 108 of package 100 is formed partially on and above the carrier body 102 and partially on and in as well as above the integrated circuit substrate 106. Thus, the redistribution structure 108 is a hybrid integrally formed redistribution structure to which both the inorganic carrier body 102 and the organic IC substrate 106 contribute. The redistribution structure 108 translates between a smaller pitch at its top main surface, i.e. at an interface to the surface mounted components 126, 134, and a larger pitch at its bottom main surface to which the IC substrate 106 and optionally also the inorganic carrier body 102 is or are electrically connected. Descriptively speaking, the upper main surface of the redistribution structure 108 has a pitch or a line space ratio corresponding to the demands of semiconductor technology which allows to connect semiconductor chip-type components 126, 134 with the exposed main surface of the redistribution structure 108. Furthermore, the lower main surface of the redistribution structure 108 has another (i.e. larger) pitch or line space ratio corresponding to the requirements of printed circuit board technology which allows to connect mounting base 158 with the exposed lower main surface of the package 100. Briefly, the redistribution structure 108 translates between smaller characteristic dimensions of semiconductor technology and larger characteristic dimensions of PCB technology.

As shown, part of the redistribution structure 108 extends downwardly into the cavity 104 and thereby forms an integral part of an upper portion of the IC substrate 106. Furthermore, the redistribution structure 108 has a larger vertical extension d1 in, on and above the integrated circuit substrate 106 compared with a smaller vertical extension d2 above the carrier body 102. This leads to a stepped spatial confinement of the redistribution structure 108 in a downward direction from a larger width W at an exterior main surface of the package 100 to a smaller width w at a lower end of the redistribution structure 108. Advantageously, this design also results in a spatial confinement of the width over which electric signals are transported through the redistribution structure 108 towards the bottom-sided interface for mounting base 158 at a lower main surface of the package 100. This may be in particular advantageous in embodiments in which the entire electricity (i.e. electric signals and electric power) shall be guided through the IC substrate 106 rather than through the inorganic carrier body 102 (for instance in an embodiment in which no electrically conductive connection structure 112 is foreseen, see for example FIG. 10, or in which the electrically conductive connection structure 112 has no electric connection or function and is used for instance for removing heat out of the package 100). According to FIG. 1, both opposing main surfaces of the integrated circuit substrate 106 comprise electrically conductive connection bumps 110 (such as pads) but no wiring lines at said main surfaces.

Still referring to FIG. 1, the upper portion of the redistribution structure 108 corresponding to the larger width W has a higher integration density (i.e. a larger number of electrically conductive structures per volume) than the lower portion of the redistribution structure 108 corresponding to the smaller width w. More specifically, the redistribution structure 108 has a first region 146 (i.e. the upper portion of the redistribution structure 108) with a first pitch and a second region 148 (i.e. the lower portion of the redistribution structure 108) with a larger second pitch compared with the first pitch. Thus, the electrically conductive layer structures 120 of the redistribution structure 108 comprise a package-exposed higher density connection region and a package-embedded lower density connection region. The number of electrically conductive elements of the electrically conductive layer structures 120 per volume of stack material is thus larger in the higher density connection region as compared with the lower density connection region. This configuration supports the functionality of the redistribution structure 108. In the shown embodiment, the integration density of the redistribution structure 108 is higher where the redistribution structure 108 has a larger width W and is smaller where the redistribution structure 108 has a smaller width w. For example, the redistribution structure 108 may provide a line/space ratio below 5 μm/5 μm. In contrast to this, the IC substrate 106 may support a line/space ratio above 5 μm/5 μm. This may bring a cost advantage for high volume manufacturing on the fine line structuring.

As shown, the lower layer structures 120, 160 of the redistribution structure 108 are formed only on and in the integrated circuit substrate 106 without extending to the carrier body 102. Some of the lower layer structures 120, 160 of the redistribution structure 108 are integrally formed with the integrated circuit substrate 106. However, the upper layer structures 120, 160 of the redistribution structure 108 are formed above the carrier body 102 and above the integrated circuit substrate 106. Since an exterior surface of the redistribution structure 108 is substantially planar, one or more electronic components 126, 134 (such as semiconductor chips) may be mounted with high accuracy on the package 100. In contrast to the planar exterior surface of the redistribution structure 108, an interior surface of the redistribution structure 108 is profiled in a stepped manner. This helps the fine line structuring formation.

As shown as well in FIG. 1, package 100 comprises a dielectric filling medium 124 covering vertical sidewalls and horizontal walls of the carrier body 102 and of the integrated circuit substrate 106. Dielectric filling medium 124 may be glue and/or may be resin from laminated sheets and may glue the IC substrate 106 in place inside of the inorganic carrier body 102. As shown, the dielectric filling medium 124 does not only fill vertical gaps between inorganic carrier body 102 and IC substrate 106 but provides also horizontal connection layers above and below the inorganic carrier body 112 and the IC substrate 106. In particular, the dielectric filling medium 124 spatially separates and mechanically connects the carrier body 102 and the redistribution structure 108. Advantageously, the dielectric filling medium 124 may comprise a low Young modulus dielectric material, for instance with a value of the Young modulus of not more than 3 GPa. Thus, the dielectric filling medium 124 may be a soft material functioning as damping buffer between the inorganic carrier body 102 and the organic integrated circuit substrate 106. Thus, the dielectric filling medium 124 may reduce a mechanical impact acting on the inorganic carrier body 102 and the organic integrated circuit substrate 106 and may thereby protect package 100 against damage.

In the framework of the package 100, the integrated circuit substrate 106 is configured for providing at least one additional function in addition to its electric control function. For instance, at least one component, in particular at least one passive component, preferably at least one capacitor 144, may be embedded in the integrated circuit substrate 106. Such a capacitor 144 may provide a voltage regulation function to the package 100 and in particular to at least one surface mounted component 126, 134 thereof. Additionally or alternatively, the IC substrate 106 may be configured for providing a heat management function, a power supply function, a high-frequency application function, a signal processing function and/or an amplifier function. As shown in FIG. 1 as well, a further capacitor 144 may be formed on the carrier body 102 and may also contribute to the electronic control function.

FIG. 2 illustrates a preform of a package 100 according to an exemplary embodiment of the disclosure.

On the left-hand side of FIG. 2, a cross-sectional view of an inorganic carrier body 102 with a plurality of cavities 104 is shown. In each of said cavities 104, a respective IC substrate 106 is inserted. As shown, different cavities 104 may have different dimensions in accordance with different dimensions of IC substrates 106 to be embedded therein. On the right-hand side of FIG. 2, a plan view of the inorganic carrier body 102 with a plurality of IC substrates 106 inserted in a plurality of cavities 104 is shown. With the architecture according to FIG. 2, it is possible to form a plurality of packages 100 together in a batch process based on the illustrated inorganic carrier body 102 and inserted IC substrates 106. After having completed manufacture, the obtained structure may be separated, for example along horizontal separation lines 170 and along vertical separation lines 172 for forming a plurality of individual packages 100. This allows to manufacture packages 100 with high throughput and on an industrial scale and simultaneously with a high yield.

FIG. 3 illustrates a cross-sectional view of a package 100 according to another exemplary embodiment of the disclosure. FIG. 4 illustrates a cross-sectional view of a package 100 according to still another exemplary embodiment of the disclosure.

The embodiments of FIG. 3 and FIG. 4 differ from the embodiment of FIG. 1 in particular in that, according to FIG. 3 and FIG. 4, the inorganic carrier body 102 has a plurality of cavities 104. In each of said cavities 104, a respective organic integrated circuit substrate 106 or 130 is embedded. Furthermore, an electronic component 126 (such as a semiconductor chip) is mounted on the exposed electrically conductive layer structures 120 of the redistribution structure 108. Said redistribution structure 108 is formed partially on and/or in the integrated circuit substrate 106, partially on and/or in the further integrated circuit substrate 130, and partially on and/or above the various portions of the inorganic carrier body 102 separated by the cavities 104. Parts of the redistribution structure 108 extend into each of the cavities 104 and form an integral part of each respective integrated circuit substrate 106, 130.

The IC substrates 106, 130 may be provided with different architectures or with the same architecture. In the described embodiment, the integrated circuit substrate 106 and the further integrated circuit substrate 130 may be configured for providing different functions in the framework of the package 100. For example, one of the integrated circuit substrates 106, 130 may be provided with one or more components (not shown) providing a high-frequency application function, whereas another one of the integrated circuit substrates 106, 130 may be provided with an integrated heat pipe (not shown) to thereby provide a heat management function.

In the embodiment of FIG. 3, construction of the core 150 of the IC substrates 106, 130 may be different, whereas the IC substrates 106, 130 have the same construction (although having different sizes) according to FIG. 4.

FIG. 5, FIG. 6, FIG. 7, FIG. 8, FIG. 9, and FIG. 10 illustrate cross-sectional views of structures obtained during carrying out a method of manufacturing a package 100, shown in FIG. 10, according to an exemplary embodiment of the disclosure.

Referring to FIG. 5, an inorganic carrier body 102, preferably a glass plate (or alternatively made of ceramic), is shown in which a through hole-type cavity 104 is formed. Cavity 104 can be created for example by glass laser cutting or deep routing. The cut inorganic carrier body 102 may then be subjected to a cleaning process. Furthermore, the cut inorganic carrier body 102 may undergo a surface treatment, for instance surface activation, for example by a plasma treatment. The through hole formed in the cut inorganic carrier body 102 may then be closed at a bottom side by attaching a temporary carrier 176 to the inorganic carrier body 102, for instance a tape.

Optionally but advantageously, one or more alignment marks 180 or fiducial may be formed in the inorganic carrier body 102, for instance by grooving. Such alignment marks 180 may be used advantageously in a subsequent process of embedding an IC substrate 106 in cavity 104, see FIG. 6. Using the inorganic carrier body 102 for forming alignment marks 180 thereon may improve the accuracy of the process of manufacturing package 100.

Referring to FIG. 6, a pre-manufactured IC substrate 106 (for example of flip chip ball grid array-(FCBGA) type, or alternatively of land grid array-(LGA) type) may then be inserted as an inlay in cavity 104 and may also be attached to the temporary carrier 176. Said process may be supported by back pressing. Gaps 178 remain between facing side walls of the IC substrate 106 and of the inorganic carrier body 102. The IC substrate 106 comprises a central core 150 which may have a glass reinforcement. The build-up of electrically insulating layer structures 160 and electrically conductive layer structures 120 on both opposing main surfaces of the central core 150 may be free of a glass reinforcement. Said build-up on the opposing main surfaces of core 150 may be symmetric or asymmetric (for instance may comprise one or more embedded capacitors 144, see FIG. 1).

Referring to FIG. 7, the inorganic carrier body 102 and the IC substrate 106 may then be connected with each other by a dielectric filling medium 124 inserted into the gaps 178 and on top of the structure shown in FIG. 6. For instance, the dielectric filling medium 124 may be glue or may be resin of a dielectric laminate. For instance, the process corresponding to FIG. 7 may be executed in a bonding press for encapsulation of the IC substrate 106.

Referring to FIG. 8, the temporary carrier 176 may then be removed, for instance by detaching a tape. The obtained structure may be flipped over, i.e. may be turned upside down.

Referring to FIG. 9, a lamination process may then be executed both on the back side and on the front side of the structure shown in FIG. 8. This may cover the structures shown in FIG. 8 both on the front side as well as on the back side by further dielectric filling medium 124. For instance, a resin sheet, a prepreg sheet, an ABF sheet or a mold film may be laminated on the front side and/or on the back side of the structure shown in FIG. 8 in order to cover the respective side with further dielectric filling medium 124.

Referring to FIG. 10, redistribution structure 108 is then formed based on a bottom portion thereof being already integrated in IC substrate 106 by laminating and patterning further layer structures 120, 160 on the upper main surface of FIG. 9. This may lead to the hybrid redistribution structure 108 being partially formed on the basis of IC substrate 106 and partially on the basis of inorganic carrier body 102. Moreover, pads 164 may be formed on the bottom main surface of the package 100 according to FIG. 10.

FIG. 11 illustrates a cross-sectional view of a package 100 according to another exemplary embodiment of the disclosure.

A difference between the embodiment of FIG. 11 and the embodiment of FIG. 4 is that, according to FIG. 11, a plurality of an electronic components 126, 134 (rather than a single electronic component 126) are mounted on the exposed redistribution structure 108. More specifically, an electronic component 126 is mounted on the redistribution structure 108 above the integrated circuit substrate 106. Beyond this, a further electronic component 134 is mounted on the redistribution structure 108 above the further integrated circuit substrate 130. Advantageously, the electronic component 126 and the further electronic component 134 may be mounted on the redistribution structure 108 in such a way that the latter functions as a bridge between the electronic component 126 and the further electronic component 134 and electrically couples both of them with each other.

Yet another difference of the embodiment of FIG. 11 compared with the previously described embodiments is that, according to FIG. 11, an exterior surface of the carrier body 102 is coated with a functional coating 142. A corresponding coating process may be executed for instance at a stage of the manufacturing process according to FIG. 5 (preferably before attaching temporary carrier 176). For example, the additional function provided by the functional coating 142 may be a prolongation of a lifetime of the package 100, a reduction of the interior mechanically and/or thermal stress, a mechanical buffer function, an adhesion promoting function, a fatigue protection, a CTE mismatch reduction function, a heat removal and/or spreading function, an electromagnetic radiation shielding function, etc.

FIG. 12 illustrates a preform of a package 100 according to an exemplary embodiment of the disclosure.

In the embodiment of FIG. 12, an additional layer build-up 114 is provided on a bottom side of the carrier body 102 and of the integrated circuit substrate 106, i.e. opposing the redistribution structure 108 (not shown in FIG. 12 but being provided on the top side of the carrier body 102 and of the integrated circuit substrate 106). The additional layer build-up 114 and the redistribution structure 108 may be asymmetric, for instance may have different thicknesses. It is also possible that the redistribution structure 108 has a higher integration density than the layer build-up 114.

What concerns the structural shape, vias in a photoimageable dielectric or polyimide may be substantially straight due to the formation by exposure for the redistribution structure 108. An interconnection structure between the redistribution structure 108 and the integrated circuit substrate 106 can be made in a via like fashion by lithography. Generally, it may be possible to form a via on a pad by using photoimageable dielectric material and exposure, after via filling or plating, just grinding the surface to expose the via.

A top side of the integrated circuit substrate 106 may be provided with metallic pillars 190 to be interconnected with further electrically conductive layer structures 120 to be formed on top thereof.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A package, comprising:
an inorganic carrier body having a cavity;
an organic integrated circuit substrate embedded in the cavity of the inorganic carrier body; and
a redistribution structure formed partially on and/or above the inorganic carrier body and partially on and/or in the organic integrated circuit substrate.

2. The package according to claim 1, wherein part of the redistribution structure extends into the cavity.

3. The package according to claim 1, wherein the redistribution structure has a larger vertical extension on and/or in the organic integrated circuit substrate than on and/or above the inorganic carrier body.

4. The package according to claim 1, wherein at least one layer structure of the redistribution structure is formed only on and/or in the organic integrated circuit substrate without extending to the inorganic carrier body.

5. The package according to claim 1, wherein at least one layer structure of the redistribution structure is formed on and/or above the inorganic carrier body and on and/or above the organic integrated circuit substrate.

6. The package according to claim 1, wherein at least one layer structure of the redistribution structure is formed as integral part of the organic integrated circuit substrate.

7. The package according to claim 1, comprising at least one of the following features:
wherein an exterior surface of the redistribution structure is substantially planar;
wherein an interior surface of the redistribution structure is profiled;
wherein the inorganic carrier body comprises at least one of glass, ceramic, metal, high stiff functional materials, and organic carriers, including carbon composite and/or aramid composite;
wherein the inorganic carrier body consists only of glass;
wherein at least one main surface of the organic integrated circuit substrate comprises electrically conductive connection bumps but no wiring lines;
the package comprises one of the following features: wherein the inorganic carrier body is free of interior electrically conductive connection structures; comprising at least one electrically conductive connection structure in an interior of the inorganic carrier body;
wherein a surface roughness Ra of the inorganic carrier body is not more than 100 nm;
wherein the organic integrated circuit substrate comprises a laminated layer stack comprising at least one electrically conductive layer structure and at least one electrically insulating layer structure;
the package comprises an electronic component mounted on the redistribution structure;
wherein the organic integrated circuit substrate is configured for providing a voltage regulation function, a heat management function, a power supply function, a high-frequency application function, a signal processing function and/or an amplifier function;
wherein the organic integrated circuit substrate is embedded in the cavity of the inorganic carrier body so as to suppress warpage and/or enhance mechanical stability of the organic integrated circuit substrate;
the package comprises at least one capacitor formed on the inorganic carrier body and/or embedded in the integrated circuit substrate.

8.-13. (canceled)

14. The package according to claim 1, further comprising a layer build-up on a side of the inorganic carrier body and of the organic integrated circuit substrate which opposes the redistribution structure wherein the layer build-up and the redistribution structure are asymmetric.

15. (canceled)

16. The package according to claim 14, wherein the redistribution structure has a higher integration density than the layer build-up.

17. (canceled)

18. The package according to claims 1, further comprising a dielectric filling medium covering at least part of at least one vertical sidewall and/or at least part of at least one horizontal wall of the inorganic carrier body and/or of the organic integrated circuit substrate.

19. The package according to claim 18, wherein the dielectric filling medium spatially separates the inorganic carrier body with respect to the redistribution structure.

20. The package according to claim 18, wherein the dielectric filling medium comprises a dielectric having a value of the Young modulus of not more than 5 GPa.

21. (canceled)

22. The package according to claim 1,
wherein the inorganic carrier body has a further cavity;
comprising a further organic integrated circuit substrate embedded in the further cavity of the carrier body; and
wherein the redistribution structure is formed partially on and/or in the further organic integrated circuit substrate.

23. The package according to claim 22, further comprising:
an electronic component mounted on the redistribution structure above the organic integrated circuit substrate; and
a further electronic component mounted on the redistribution structure above the further organic integrated circuit substrate.

24. The package according to claim 22, wherein the organic integrated circuit substrate and the further organic integrated circuit substrate are configured for providing different functions.

25. The package according to claim 1, further comprising an electronic component and a further electronic component mounted on the redistribution structure which is configured as a bridge between the electronic component and the further electronic component.

26. (canceled)

27. The package according to claim 1, further comprising an optical communication path extending through the inorganic carrier body.

28. The package according to claim 1, comprising at least one of the following features:
wherein the redistribution structure has a first region with a first pitch and a second region with a second pitch, the second pitch being different than the first pitch;
wherein the redistribution structure has a pitch on and/or above the inorganic carrier body differing from another pitch, preferably a larger pitch, on and/or in the organic integrated circuit substrate.

29. The package according to claim 1, wherein at least part of the inorganic carrier body is coated with a functional coating.

30.-31. (canceled)

32. A method of manufacturing a package, the method comprising:
providing an inorganic carrier body having a cavity;
embedding an organic integrated circuit substrate in the cavity of the inorganic carrier body; and
forming a redistribution structure partially on and/or above the inorganic carrier body and partially on and/or in the organic integrated circuit substrate.
